(19) United States
(12) Patent Application Publication
(10) Pub. No.: US 2026/0332378 A1
(43) Pub. Date: Oct. 22, 2026

(54) COORDINATED STARTUP FOR CRYSTAL-LESS COMMUNICATION DEVICES

(71) Applicant: Axonne, Inc., Sunnyvale, CA (US)

(72) Inventor: William LO, Cupertino, CA (US)

(21) Appl. No.: 19/653,744

(22) Filed: Apr. 21, 2026

Related U.S. Application Data
(60) Provisional application No. 63/791,937, filed on Apr. 21, 2025.
(60) Provisional application No. 63/875,735, filed on Sep. 4, 2025.

(51) Int. Cl. H04L 7/00; H03K 5/13; H03M 5/12

(52) U.S. Cl. CPC H04L 7/0004; H03K 5/13; H03M 5/12

(57) ABSTRACT

A method includes periodically sending first pulses from a master device to a slave device, detecting energy of the first pulses at the slave device, and sending second pulses from the slave device to the master device upon detecting energy of a first predetermined number of the first pulses at the slave device. The second pulses are offset relative to the first pulses. The method comprises ceasing sending the first pulses from the master device to the slave device after receiving a second predetermined number of the second pulses from the slave device at the master device, and ceasing sending the second pulses from the slave device to the master device after not receiving any pulse from the master device at the slave device for a predetermined time period.

### CROSS-REFERENCE TO RELATED APPLICATIONS

This application claims the benefit of U.S. Provisional Application No. 63/791,937, filed on Apr. 21, 2025, and U.S. Provisional Application No. 63/875,735, filed on Sep. 4, 2025. The entire disclosures of the applications referenced above are incorporated herein by reference.

### FIELD

The present disclosure relates generally to communication devices used in communication systems and more particularly to coordinated startup for crystal-less communication devices used in automotive communication systems.

### BACKGROUND

The background description provided herein is for the purpose of generally presenting the context of the disclosure. Work of the presently named inventor, to the extent the work is described in this background section, as well as aspects of the description that may not otherwise qualify as prior art at the time of filing, are neither expressly nor impliedly admitted as prior art against the present disclosure.

IEEE 802.3ch and IEEE 802.3cy are automotive Ethernet standards. According to these standards, two devices in a vehicle communicate point-to-point via a single pair of twisted wires. In IEEE 802.3ch, master and slave devices define physical layer (PHY) timing for synchronized communication. The master device provides the timing and the slave device locks to that timing, which allows for reliable high-speed bidirectional communication over a single pair of twisted wires in automotive environments. In IEEE802.3cy, master and slave devices define clock and link synchronization roles as follows. The master PHY uses an internal clock for timing. The slave PHY recovers timing from signals received from the master to establish a reliable link. The master device actively polls and the slave device responds, often using specific synchronization frames called SEND_S for clock alignment, which allows for deterministic real-time communication.

Two devices (e.g., master and slave) that communicate with each other via a communication link are generally called link partners. The link partners typically perform synchronization and training procedures upon power-up and power-on reset (POR). Some devices also use echo canceling system to reduce interference that can be caused by signals reflected from within the devices and/or from the link partner.

### SUMMARY

A method comprises periodically sending first pulses from a master device to a slave device, detecting energy of the first pulses at the slave device, and sending second pulses from the slave device to the master device upon detecting energy of a first predetermined number of the first pulses at the slave device. The second pulses are offset relative to the first pulses. The method comprises ceasing sending the first pulses from the master device to the slave device after receiving a second predetermined number of the second pulses from the slave device at the master device, and ceasing sending the second pulses from the slave device to the master device after not receiving any pulse from the master device at the slave device for a predetermined time period.

In other features, the first and second pulses comprise a pseudo-random pattern.

In other features, the first and second pulses comprise data encoded by Manchester encoding or differential Manchester encoding.

In other features, the method further comprises sending the first and second pulses spaced within intervals. The first and second pulses have a first duration. The intervals have a second duration that is based on the first duration and a round-trip propagation delay on a cable connecting the master and slave devices.

In other features, the method further comprises sending the first and second pulses such that, in each interval, a spacing between one of the first pulses and one of the second pulses is at least a sum of the first duration and the round-trip propagation delay.

In other features, the method further comprises setting the second duration of the intervals based on a length of the cable.

In other features, the method further comprises setting the second duration of the intervals to a multiple of a sum of the first duration and the round-trip propagation delay.

In other features, the method further comprises sending the first and second pulses to represent one bit in each interval; sending the first pulses comprising sending, in each interval, one pulse for a bit 0 or two pulses for a bit 1; and sending the second pulses comprising sending, in each interval, one pulse for a bit 0 or one pulse for a bit 1.

In other features, the method further comprises positioning, in sending the first pulses in each interval, the one pulse for a bit 0 or a first one of the two pulses for a bit 1 at a start of the interval, and a second one of the two pulses for a bit 1 in middle of the interval. The method further comprises positioning, in sending the second pulses in each interval, the one pulse for a bit 0 at a first offset relative to the start of the interval, and the one pulse for a bit 1 at a second offset relative to the start of the interval or relative to middle of the interval.

In other features, the method further comprises setting the first offset equal to a sum of the first duration and the round-trip propagation delay, and setting the second offset equal to a multiple of the first offset when measured from the start of the interval or equal to the sum of the first duration and the round-trip propagation delay when measured from the middle of the interval.

In other features, the method further comprises, at the slave device: generating a clock without using a crystal oscillator, counting number of cycles of the clock between the first pulses for a plurality of the intervals, determining an average count of the cycles of the clock per interval, and setting the first and second offsets based on the average count.

In other features, the method further comprises, at the slave device: generating a clock without using a crystal oscillator, counting number of cycles of the clock between the first pulses for a plurality of the intervals, and determining an average count of the cycles of the clock per interval.

In other features, the method further comprises, at the slave device: generating a clock without using a crystal oscillator, counting number of cycles of the clock between the first pulses for a plurality of the intervals, determining an average count of the cycles of the clock per interval, and adjusting the clock until the average count is within a predetermined range of an expected count without a frequency offset between the clock at the slave device and a clock at the master device.

In other features, the method further comprises, at the slave device: generating a clock without using a crystal oscillator, counting number of cycles of the clock between the first pulses for a plurality of the intervals, determining an average count of the cycles of the clock per interval, and adjusting the clock until the average count is within a predetermined range of an expected count without a frequency offset between the clock at the slave device and a clock at the master device.

In other features, the method further comprises sending the first and second pulses to represent one bit in each interval; sending, in each interval, the first pulses comprising one pulse for a bit 0 and one pulse for a bit 1, each having the first duration and a spacing within the interval; and sending, in each interval, the second pulses comprising one pulse for a bit 0 and one pulse for a bit 1, each having the first duration and the spacing within the interval.

In other features, the method further comprises, when noise is to be disregarded, halving the second duration by including a single pulse in each of the first and second pulses.

In still other features, a system comprises a master device and a slave device a slave device coupled to the master device by the cable. The master device comprises a first pulse generator and a first pulse detector. The first pulse generator is configured to generate and periodically send first pulses over a cable. The first pulse detector is configured to detect incoming pulses on the cable. The slave device comprises a second pulse generator and a second pulse detector. The second pulse detector is configured to detect the first pulses on the cable. The second pulse generator is configured to generate and send second pulses over the cable in response to the second pulse detector detecting a first predetermined number of the first pulses on the cable. The second pulses are offset relative to the first pulses. The first pulse generator is configured to stop sending the first pulses in response to the first pulse detector detecting a second predetermined number of the second pulses on the cable. The second pulse generator is configured to stop sending the second pulses after the second pulse detector not detecting any pulse from the master device for a predetermined time period.

In other features, the first and second pulses comprise a pseudo-random pattern.

In other features, the first and second pulses comprise data encoded by Manchester encoding or differential Manchester encoding.

In other features, the first and second pulse generators are configured to send the first and second pulses spaced within intervals. The first and second pulses have a first duration. The intervals have a second duration that is based on the first duration and a round-trip propagation delay on the cable.

In other features, the first and second pulse generators are configured to send the first and second pulses such that, in each interval, a spacing between one of the first pulses and one of the second pulses is at least a sum of the first duration and the round-trip propagation delay.

In other features, the second duration of the intervals based on a length of the cable.

In other features, the second duration of the intervals is a multiple of a sum of the first duration and the round-trip propagation delay.

In other features, the first and second pulse generators are configured to send the first and second pulses to represent one bit in each interval. The first pulse generator is configured to send the first pulses comprising, in each interval, one pulse for a bit 0 or two pulses for a bit 1. The second pulse generator is configured to send the second pulses comprising, in each interval, one pulse for a bit 0 or one pulse for a bit 1.

In other features, the first pulse generator is configured to position, in sending the first pulses in each interval, the one pulse for a bit 0 or a first one of the two pulses for a bit 1 at a start of the interval, and a second one of the two pulses for a bit 1 in middle of the interval. The second pulse generator is configured to position, in sending the second pulses in each interval, the one pulse for a bit 0 at a first offset relative to the start of the interval, and the one pulse for a bit 1 at a second offset relative to the start of the interval or relative to middle of the interval.

In other features, the second pulse generator is configured to set: the first offset equal to a sum of the first duration and the round-trip propagation delay; and the second offset equal to a multiple of the first offset when measured from the start of the interval or equal to the sum of the first duration and the round-trip propagation delay when measured from the middle of the interval.

In other features, the slave device further comprises a clock generator and a control circuit. The clock generator is configured to generate a clock without using a crystal oscillator. The control circuit is configured to count number of cycles of the clock between the first pulses for a plurality of the intervals, determine an average count of the cycles of the clock per interval, and set the first and second offsets based on the average count.

In other features, the slave device further comprises a clock generator and a control circuit. The clock generator is configured to generate a clock without using a crystal oscillator. The control circuit is configured to count number of cycles of the clock between the first pulses for a plurality of the intervals, and determine an average count of the cycles of the clock per interval.

In other features, the slave device further comprises a clock generator and a control circuit. The clock generator is configured to generate a clock without using a crystal oscillator. The control circuit is configured to count number of cycles of the clock between the first pulses for a plurality of the intervals, determine an average count of the cycles of the clock per interval, and adjust the clock until the average count within a predetermined range of an expected count without a frequency offset between the clock and a clock at the master device.

In other features, the slave device further comprises a clock generator and a control circuit. The clock generator is configured to generate a clock without using a crystal oscillator. The control circuit is configured to count number of cycles of the clock between the first pulses for a plurality of the intervals, determine an average count of the cycles of the clock per interval, and adjust the clock until the average count within a predetermined range of an expected count without a frequency offset between the clock and a clock at the master device.

In other features, the first and second pulse generators are configured to send the first and second pulses to represent one bit in each interval. The first pulse generator is configured to send, in each interval, the first pulses comprising one pulse for a bit 0 and one pulse for a bit 1, each having the first duration and a spacing within the interval. The second pulse generator is configured to send, in each interval, the second pulses comprising one pulse for a bit 0 and one pulse for a bit 1, each having the first duration and the spacing within the interval.

In other features, the second duration is halved by including a single pulse in each of the first and second pulses when noise is to be disregarded.

In still other features, a slave device coupled to a master device by a cable comprises a pulse detector and a pulse generator. The pulse detector is configured to detect first pulses on the cable. The pulse generator is configured to send second pulses on the cable in response to the pulse detector detecting a first predetermined number of the first pulses. The second pulses are offset relative to the first pulses. The pulse generator is configured to stop sending the second pulses after the pulse detector not detecting any pulse from the master device for a predetermined time period.

In other features, the first and second pulses comprise a pseudo-random pattern.

In other features, the first and second pulses comprise data encoded by Manchester encoding or differential Manchester encoding.

In other features, the pulse detector is configured to receive the first pulses spaced within intervals. The pulse generator is configured to send the second pulses spaced within the intervals. The first and second pulses have a first duration. The intervals have a second duration that is based on the first duration and a round-trip propagation delay on the cable.

In other features, the pulse generator is configured to send the second pulses such that, in each interval, a spacing between one of the first pulses and one of the second pulses is at least a sum of the first duration and the round-trip propagation delay.

In other features, the second duration of the intervals is based on a length of the cable.

In other features, the second duration of the intervals is a multiple of a sum of the first duration and the round-trip propagation delay.

In other features, the first and second pulses represent one bit in each interval. The first pulses comprise, in each interval, one pulse for a bit 0 or two pulses for a bit 1. The pulse generator is configured to send the second pulses comprising, in each interval, one pulse for a bit 0 or one pulse for a bit 1.

In other features, the first pulses comprise, in each interval, the one pulse for a bit 0 or a first one of the two pulses for a bit 1 at a start of the interval, and a second one of the two pulses for a bit 1 in middle of the interval. The pulse generator is configured to position, in sending the second pulses in each interval, the one pulse for a bit 0 at a first offset relative to the start of the interval, and the one pulse for a bit 1 at a second offset relative to the start of the interval or relative to middle of the interval.

In other features, the pulse generator is configured to set the first offset equal to a sum of the first duration and the round-trip propagation delay. The pulse generator is configured to set the second offset equal to a multiple of the first offset when measured from the start of the interval or equal to the sum of the first duration and the round-trip propagation delay when measured from the middle of the interval.

In other features, the slave device further comprises a clock generator and a control circuit. The clock generator is configured to generate a clock without using a crystal oscillator. The control circuit is configured to count number of cycles of the clock between the first pulses for a plurality of the intervals, determine an average count of the cycles of the clock per interval, and set the first and second offsets based on the average count.

In other features, the slave device further comprises a clock generator and a control circuit. The clock generator is configured to generate a clock without using a crystal oscillator. The control circuit is configured to count number of cycles of the clock between the first pulses for a plurality of the intervals, and determine an average count of the cycles of the clock per interval.

In other features, the slave device further comprises a clock generator and a control circuit. The clock generator is configured to generate a clock without using a crystal oscillator. The control circuit is configured to count number of cycles of the clock between the first pulses for a plurality of the intervals, determine an average count of the cycles of the clock per interval, and adjust the clock until the average count within a predetermined range of an expected count without a frequency offset between the clock and a clock at the master device.

In other features, the slave device further comprises a clock generator and a control circuit. The clock generator is configured to generate a clock without using a crystal oscillator. The control circuit configured to count number of cycles of the clock between the first pulses for a plurality of the intervals, determine an average count of the cycles of the clock per interval, and adjust the clock until the average count within a predetermined range of an expected count without a frequency offset between the clock and a clock at the master device.

In other features, the first and second pulses represent one bit in each interval. The first pulses comprise one pulse for a bit 0 and one pulse for a bit 1, each having the first duration and a spacing within the interval. The pulse generator is configured to send, in each interval, the second pulses comprising one pulse for a bit 0 and one pulse for a bit 1, each having the first duration and the spacing within the interval.

In other features, the second duration is halved by including a single pulse in each of the first and second pulses when noise is to be disregarded.

In still other features, a method for a slave device coupled to a master device by a cable comprises detecting first pulses on the cable at the slave device; and sending second pulses on the cable from the slave device in response to detecting, at the slave device, a first predetermined number of the first pulses. The second pulses are offset relative to the first pulses. The method comprises ceasing sending the second pulses after not detecting any pulse from the master device for a predetermined time period at the slave device.

In other features, the first and second pulses comprise a pseudo-random pattern.

In other features, the first and second pulses comprise data encoded by Manchester encoding or differential Manchester encoding.

In other features, the method further comprises receiving the first pulses spaced within intervals, and sending the second pulses spaced within the intervals. The first and second pulses have a first duration. The intervals have a second duration that is based on the first duration and a round-trip propagation delay on the cable.

In other features, the method further comprises sending the second pulses such that, in each interval, a spacing between one of the first pulses and one of the second pulses is at least a sum of the first duration and the round-trip propagation delay.

In other features, the second duration of the intervals is based on a length of the cable.

In other features, the second duration of the intervals is a multiple of a sum of the first duration and the round-trip propagation delay.

In other features, the first and second pulses represent one bit in each interval. The first pulses comprise, in each interval, one pulse for a bit 0 or two pulses for a bit 1. The method further comprises sending the second pulses comprising, in each interval, one pulse for a bit 0 or one pulse for a bit 1.

In other features, the first pulses comprise, in each interval, the one pulse for a bit 0 or a first one of the two pulses for a bit 1 at a start of the interval, and a second one of the two pulses for a bit 1 in middle of the interval. The method further comprises positioning, in sending the second pulses in each interval, the one pulse for a bit 0 at a first offset relative to the start of the interval, and the one pulse for a bit 1 at a second offset relative to the start of the interval or relative to middle of the interval.

In other features, the method further comprises setting the first offset equal to a sum of the first duration and the round-trip propagation delay. The method further comprises setting the second offset equal to a multiple of the first offset when measured from the start of the interval or equal to the sum of the first duration and the round-trip propagation delay when measured from the middle of the interval.

In other features, the method further comprises, at the slave device: generating a clock without using a crystal oscillator, counting number of cycles of the clock between the first pulses for a plurality of the intervals, determining an average count of the cycles of the clock per interval, and setting the first and second offsets based on the average count.

In other features, the method further comprises, at the slave device: generating a clock without using a crystal oscillator, counting number of cycles of the clock between the first pulses for a plurality of the intervals, and determining an average count of the cycles of the clock per interval.

In other features, the method further comprises, at the slave device: generating a clock without using a crystal oscillator, counting number of cycles of the clock between the first pulses for a plurality of the intervals, determining an average count of the cycles of the clock per interval, and adjusting the clock until the average count within a predetermined range of an expected count without a frequency offset between the clock and a clock at the master device.

In other features, the method further comprises, at the slave device: generating a clock without using a crystal oscillator, counting number of cycles of the clock between the first pulses for a plurality of the intervals, determining an average count of the cycles of the clock per interval, and adjusting the clock until the average count within a predetermined range of an expected count without a frequency offset between the clock and a clock at the master device.

In other features, the first and second pulses represent one bit in each interval. The first pulses comprise one pulse for a bit 0 and one pulse for a bit 1, each having the first duration and a spacing within the interval. The method further comprises sending, in each interval, the second pulses comprising one pulse for a bit 0 and one pulse for a bit 1, each having the first duration and the spacing within the interval.

In other features, the method further comprises, when noise is to be disregarded, halving the second duration by including a single pulse in each of the first and second pulses.

In still other features, a master device coupled to a slave device by a cable comprises a pulse generator and a pulse detector. The pulse generator is configured to generate and periodically send first pulses over the cable. The pulse detector is configured to detect second pulses received on the cable in response to the pulse generator sending the first pulses over the cable. The pulse generator is configured to stop sending the first pulses in response to the pulse detector detecting a predetermined number of the second pulses on the cable.

In other features, the pulse detector is configured to continue to detect the second pulses for a predetermined time period after the pulse generator stops sending the first pulses.

In other features, the first and second pulses comprise a pseudo-random pattern.

In other features, the first and second pulses comprise data encoded by Manchester encoding or differential Manchester encoding.

In other features, the pulse generator is configured to send the first pulses spaced within intervals. The pulse detector is configured to receive the second pulses spaced within intervals. The first and second pulses have a first duration. The intervals have a second duration that is based on the first duration and a round-trip propagation delay on the cable.

In other features, in each interval, a spacing between one of the first pulses and one of the second pulses is at least a sum of the first duration and the round-trip propagation delay.

In other features, the pulse generator is configured to set the second duration of the intervals based on a length of the cable.

In other features, the pulse generator is configured to set the second duration of the intervals to a multiple of a sum of the first duration and the round-trip propagation delay.

In other features, the first and second pulses represent one bit in each interval. The pulse generator is configured to send the first pulses comprising, in each interval, one pulse for a bit 0 or two pulses for a bit 1. The second pulses comprise, in each interval, one pulse for a bit 0 or one pulse for a bit 1.

In other features, the pulse generator is configured to position, in sending the first pulses in each interval, the one pulse for a bit 0 or a first one of the two pulses for a bit 1 at a start of the interval, and a second one of the two pulses for a bit 1 in middle of the interval. The second pulses comprise, in each interval, the one pulse for a bit 0 at a first offset relative to the start of the interval, and the one pulse for a bit 1 at a second offset relative to the start of the interval or relative to middle of the interval.

In other features, the first offset equal to a sum of the first duration and the round-trip propagation delay. The second offset equal to a multiple of the first offset when measured from the start of the interval or equal to the sum of the first duration and the round-trip propagation delay when measured from the middle of the interval.

In other features, the second duration is halved by including a single pulse in each of the first and second pulses when noise is to be disregarded.

In still other features, a method for a master device coupled to a slave device by a cable comprises periodically sending first pulses from the master device over the cable, detecting second pulses received on the cable at the master device in response sending the first pulses over the cable, and ceasing sending the first pulses in response to detecting a predetermined number of the second pulses on the cable.

In other features, the method further comprises continuing to detect the second pulses for a predetermined time period after ceasing sending the first pulses.

In other features, the first and second pulses comprise a pseudo-random pattern.

In other features, the first and second pulses comprise data encoded by Manchester encoding or differential Manchester encoding.

In other features, the method further comprises sending the first pulses spaced within intervals, and receiving the second pulses spaced within intervals. The first and second pulses have a first duration. The intervals have a second duration that is based on the first duration and a round-trip propagation delay on the cable.

In other features, in each interval, a spacing between one of the first pulses and one of the second pulses is at least a sum of the first duration and the round-trip propagation delay.

In other features, the method further comprises setting the second duration of the intervals based on a length of the cable.

In other features, the method further comprises setting the second duration of the intervals to a multiple of a sum of the first duration and the round-trip propagation delay.

In other features, the first and second pulses represent one bit in each interval. The second pulses comprise, in each interval, one pulse for a bit 0 or one pulse for a bit 1. The method further comprises sending the first pulses comprising, in each interval, one pulse for a bit 0 or two pulses for a bit 1.

In other features, the second pulses comprise, in each interval, the one pulse for a bit 0 at a first offset relative to a start of the interval, and the one pulse for a bit 1 at a second offset relative to the start of the interval or relative to middle of the interval. The method further comprises positioning, in sending the first pulses in each interval, the one pulse for a bit 0 or a first one of the two pulses for a bit 1 at the start of the interval, and a second one of the two pulses for a bit 1 in middle of the interval.

In other features, the first offset equal to a sum of the first duration and the round-trip propagation delay. The second offset equal to a multiple of the first offset when measured from the start of the interval or equal to the sum of the first duration and the round-trip propagation delay when measured from the middle of the interval.

In other features, the method further comprises, when noise is to be disregarded, halving the second duration by including a single pulse in each of the first and second pulses.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF DRAWINGS

FIG. 1 is a functional block diagram of a communication system comprising a master device coupled to a slave device by a link.

FIG. 2 is a functional block diagram of a transceiver of the master device of FIG. 1.

FIG. 3 is a functional block diagram of a transceiver of the slave device of FIG. 1.

FIGS. 4-6 show methods of link synchronization between the master and slave devices of FIG. 1.

FIG. 7 shows a method to synchronize startup between the master and slave devices of FIG. 1 prior to training.

FIG. 8 shows an example of randomizing pulses output by the master and slave devices of FIG. 1 to synchronize startup between the master and slave devices prior to training.

FIGS. 9-11 show examples of setting interval spacing and offset spacing to randomize the pulse output by the master and slave devices of FIG. 1 to synchronize startup between the master and slave devices prior to training.

FIGS. 12 and 13 show additional examples of interval spacing and offset spacing.

FIG. 14 shows a method of sending offset pulses from the slave device when a local clock of the slave device is allowed to be a free-running clock.

FIG. 15 shows a method of adjusting the local clock of the slave device.

FIG. 16 shows a simplified scheme to synchronize the startup between the master and slave devices of FIG. 1 prior to training without randomization.

FIG. 17 shows a state diagram showing states of the master and slave devices of FIG. 1 during the synchronizing of the startup between the master and slave devices prior to training.

FIG. 18 shows a method of transmitting pulses from the master device.

FIG. 19 shows a method of detecting pulses at the slave device.

FIG. 20 shows a method of transmitting pulses from the slave device.

FIG. 21 shows a method of detecting pulses at the master device.

In the drawings, reference numbers may be reused to identify similar and/or identical elements.

### DESCRIPTION

When echo cancelling is used, a typical startup sequence between master and slave devices is as follows. One side (master device) starts to transmit and the other side (slave device) remains silent. During this time, the master device trains the echo canceller of the master device while the slave device performs timing recovery and trains the receiver of the slave device. Once both sides (master and slave devices) complete this step, the slave device also transmits. During this phase of training, both devices (master and slave devices) train their echo cancellers and receivers and perform timing recovery.

Before the training starts, some mechanism is used to indicate when both devices (master and slave devices) are ready to start the training sequence. The desirable properties are that one device limits its transmit signal until both devices are present and ready to start, the detection can be completed quickly, the detection can be reliable in the presence of noise, and circuits can be implemented inexpensively.

In some systems such as 1000BASE-T1, 2.5GBASE-T1, 5GBASE-T1, 10GBASE-T1, 25GBASE-T1, the devices use a link synchronization mechanism as defined in IEEE 802.3 Clause 97, Clause 149(802.3ch) and Clause 165(802.3cy) to detect when both devices are ready to start training. In this particular mechanism, the master device transmits short bursts of a known pattern followed by periods of silence. Since the pattern is known, a matched filter can be used at the receiver to detect this pattern. With a good choice of known pattern, the detection reliability is relatively high in the presence of noise, and the detection can be performed in a relatively short amount of time.

However, detection using the matched filter requires both devices to have clock references whose frequency offset is less than 2% for the matched filter to work. The matched filter is also relatively expensive to implement compared to no filtering. The cost of the matched filter varies linearly with the length of the known pattern. Accordingly, a longer length pattern provides more reliable detection but also increases cost.

To meet the frequency offset requirement, both devices (master and slave devices) need an external clock reference. The external clock reference is typically a crystal oscillator. It is advantageous if the external clock reference is not required in a slave device. In a typical automotive deployment, the slave device is usually in the form of a camera, which is used to detect objects when a vehicle backs up, or some other sensor. The slave device such as a camera is cost-sensitive and is also housed in a relatively small enclosure (as are many other sensors). Eliminating external clock reference component (e.g., crystal oscillator) saves both cost and space. Usually, the clock source such as a crystal oscillator can be replaced with some form of signal where a clock is embedded with the data. Examples of such signals include signals encoded using Manchester encoding, differential Manchester encoding (DME), or 8bit-10bit encoding.

It is relatively easy to tune a PLL or an internal oscillator on the slave device to match the frequency of the master device if the signal sent by the master device is continuous. However, the stop-and-go nature of the transmit signal from the master device during link synchronization and not during normal operation makes it tricky and/or takes relatively long time to get the frequency offset to be within a range for the detection by the matched filters to reliably work on both the slave and master devices.

It would be advantageous to have an alternate link synchronization mechanism that has the above desirable properties but avoids the use of an expensive matched filter and the stringent initial frequency offset requirement of the PLL that is required by the matched filter. The present disclosure provides an alternative mechanism that achieves this goal with a detection time that is longer compared to the use of a matched filter. However, this detection time should be less than the time required to adjust the frequency offset of the PLL to an accuracy required by the matched filter. The alternative mechanism of the present disclosure also achieves this goal as described below in detail.

Specifically, the present disclosure eliminates the matched filters and the stringent frequency matching required by the matched filters. Instead, as described below in detail, the master and slave devices use timers. The timer of the master device is based on an accurate clock generated by a crystal oscillator while the timer of the slave device is based on an inaccurate free-running clock generator. The time intervals between the two timers will be different because the respective clocks are running at different rates. The timers count from 0 to N though sometimes the counts will be greater than N or less than N before resetting. A control logic shown in FIG. 19 and selection of the interval and pulse spacing shown in FIGS. 9-13 make the system insensitive to the difference between the two clocks.

### Communiction System Example

FIG. 1 shows an example of a communication system 10 comprising a first device 12 and a second device 14 configured to communicate with each other via a communication link 16. For example, the first device 12 can be a master device, and the second device 14 can be a slave device. For example, the communication link (or simply the link) 16 can be a wireline link (a single twisted pair of wires) in a wired automotive Ethernet network.

The first (master) device 12 comprises a first transceiver (XCVR) 18, and the second (slave) device 14 comprises a second transceiver (XCVR) 20. The first and second transceivers 18, 20 are configured to communicate with each other via the link 16. Each of the first and second transceivers 18, 20 comprises a transmitter (TX) and a receiver (RX). Transmissions from the transmitter of the first device 12 are received by the receiver of the second device 14 via the link 16, and transmissions from the second device 14 are received by the receiver of the first device 12 via the link 16. The first and second devices 12, 14 can synchronize startup procedure upon power-up or power-on reset (POR) as described below in further detail.

FIG. 2 shows the first transceiver 18 of the first (master) device 12 in further detail. The first transceiver 18 comprises a first control circuit 100, a first pulse generator 102, a first pulse detector 104, a first clock generator 108, a first timer 110, and a crystal oscillator 112 (or any other suitable fixed clock reference). The first pulse generator 102 generates first pulses (SEND_S) and periodically transmits the first pulses (shown as Data Out) to the slave device 14 over the link 16 as described below in detail. For example, the first pulse generator 102 comprises an encoder (not shown) to encode a pseudo-random sequence of bits to generate the first pulses comprising the encoded bits. The first pulse detector 104 detects energy of the second pulses (shown as Data In) received from the slave device 14 over the link 16.

The first clock generator 108 generates a first clock using an external fixed clock reference such as the crystal oscillator 112. The first clock generator 108 outputs the first clock to the first pulse generator 102 and the first timer 110. The operation of the first timer 110 is described below in detail.

The first control circuit 100 controls the first pulse generator 102 (e.g., to set pulse duration and spacing and to set interval duration, also called interval spacing) partly based on the output of the first pulse detector 104 and the first timer 110 as described below in detail. The first control circuit 100 comprises a processor and memory storing instructions (both not shown) to perform the functions and operations of the master device 12 described below and to perform of the methods described below. The first control circuit 100 performs these functions and operations by controlling the components of the first transceiver 18. The first control circuit 100 can be state machines such as those shown in FIGS. 17-21.

FIG. 3 shows the second transceiver 20 of the second (slave) device 14 in further detail. The second transceiver 20 comprises a second control circuit 150, a second pulse generator 152, a second pulse detector 154, a second clock generator 158, and a second timer 160. The second transceiver 20 of the slave device 14 does not comprise a fixed clock reference such as a crystal oscillator and the second clock generator 158 does not use a fixed clock reference such as a crystal oscillator. The second pulse generator 152 generates second pulses (SEND_S) and transmits the second pulses (shown as Data Out) to the master device 12 over the link 16. For example, the second pulse generator 152 comprises an encoder (not shown) to encode a pseudo-random sequence of bits to generate the second pulses comprising the encoded bits. In some examples, the second pulses are offset relative to the first pulses as described below in detail. The second pulse detector 154 detects energy of the first pulses (shown as Data In) received from the master device 12 over the link 16.

The second clock generator 158 generates a second clock without using an external reference such as a crystal oscillator. The second clock generator 158 generates the second clock using a PLL (not shown). The second clock generator 158 outputs the second clock to the second control circuit 150, the second pulse generator 152, and the second timer 160. The operation of the second timer 160 is described below in detail.

The second control circuit 150 controls the second pulse generator 152 (e.g., to set pulse duration and spacing and to set interval spacing) partly based on the output of the second pulse detector 154 and the second timer 160 as described below in detail. The second control circuit 150 controls the second clock generator 158 (e.g., to synchronize the second clock to the first clock by adjusting the PLL) as described below in detail. The second control circuit 150 comprises a processor and memory storing instructions (both not shown) to perform the operations of the slave device 14 described below and to perform portions of the methods described below. The second control circuit 150 performs these functions and operations by controlling the components of the second transceiver 20.

In the remaining figures showing timing diagrams, “Master” denotes the signal sent by the master device as seen at the master device, and “Slave” denotes the signal sent by the slave device as seen at the master device. Throughout the present disclosure, pulses sent by the master device 12 are called first pulses, and pulses sent by the slave device 14 are called second pulses. In the following description, functions, operations, and methods performed by the master and slave device 12, 14 can be performed by one or more of the components of the master and slave device 12, 14 shown in FIGS. 1-3. For example, different portions of the methods can be performed by different components of the transceivers 18, 20 of the master and slave devices 12, 14 shown in FIGS. 1-3.

### Methods of Synchronizing Startup

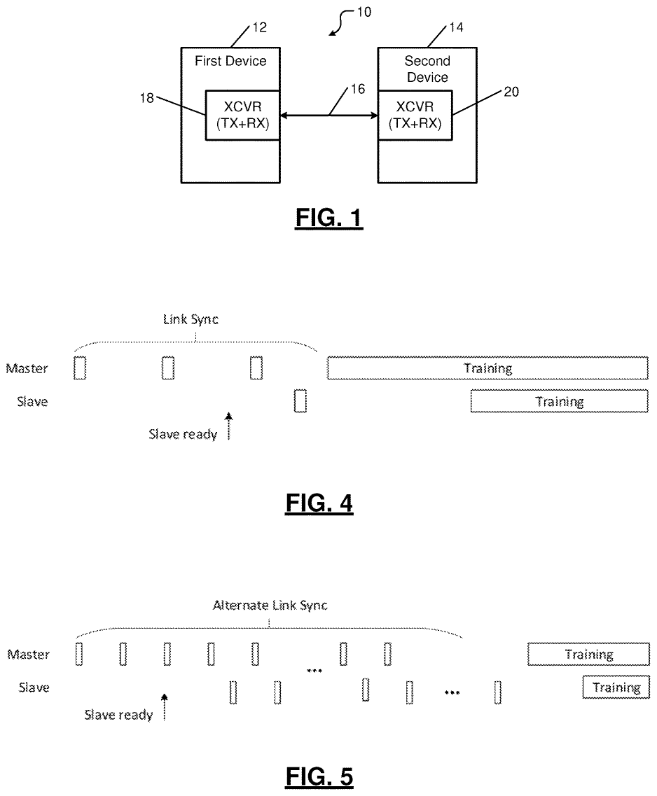

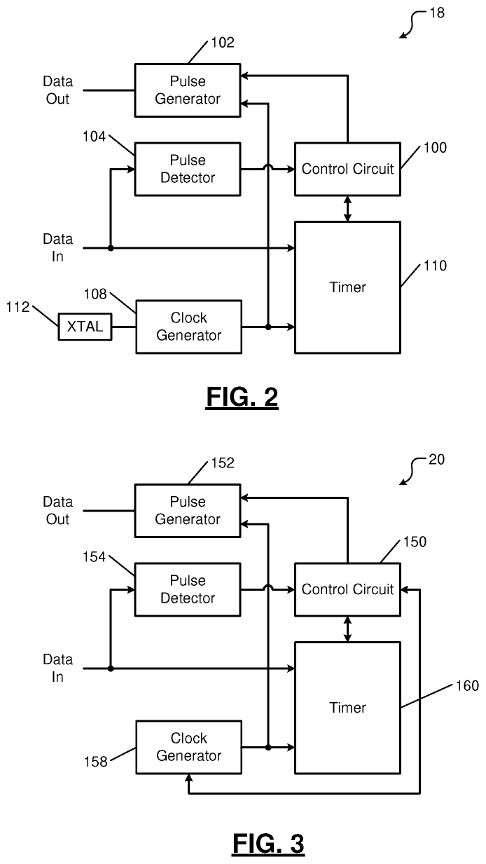

FIG. 4 shows one method to synchronize the startup between two devices (the master and slave devices 12, 14) prior to training, which is to simply send long pulses as described in the following paragraph, which needs good frequency matching to work. In this method, the master device 12 periodically sends pulses interspersed by a quiet time (duration between the pulses) until the slave device 14 responds to indicate that the slave device 14 is ready.

However, in the presence of noise, the noise may be mistaken for a valid pulse, and the master device 12 may falsely initiate training. In the link synchronization mechanism in IEEE 802.3 clauses 97, 149, and 165, the master device sends a signal with pulses of several hundred symbols of a known sequence so that the sequence can be detected with a high probability by a second matched filter at the receiver of the slave device.

FIG. 5 shows an alternate method to synchronize the startup between two devices (the master and slave devices 12, 14) prior to training, which is to periodically send shorter pulses and detect the energy of the pulses at the receiver instead of trying to detect the sequence with matched filters. When the slave device 14 is ready and detects the first pulses from the master device 12, the slave device 14 sends the second pulses that are offset relative to the first pulses received from the master device 12 so that the master device 12 can detect the second pulses sent by the slave device 14.

However, the slave device 14 need not respond by sending the second pulses to the master device 12 immediately (as soon as the slave device 14 starts receiving the first pulses from the master device 12). Rather, the slave device 14 can wait until the slave device 14 receives and detects sufficient number (e.g., a first predetermined number) of the first pulses from the master device 12 before responding by transmitting the offset second pulses to the master device 12.

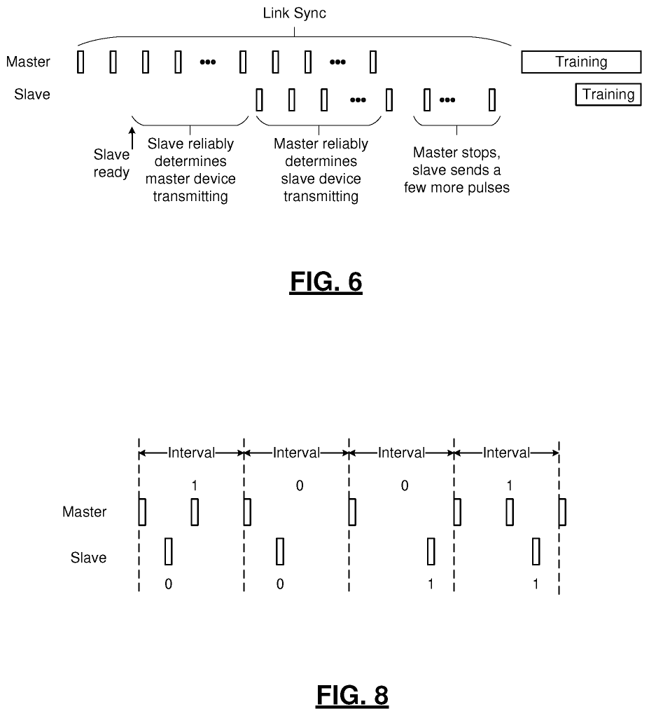

FIG. 6 shows that the master device 12 continues to send the first pulses until the master device 12 also receives and detects sufficient number (e.g., a second predetermined number) of the second pulses from the slave device 14 before the master device 12 stops sending the first pulses to the slave device 14. The slave device 14 can continue to send the offset second pulses to the master device 12 until the slave device 14 misses (does not receive) sufficient number of pulses from the master device 12 (e.g., over a predetermined period of time) to determine that the master device 12 has in fact stopped transmitting the first pulses.

The first and second pulses can be relatively short (in duration) and can be only a few symbols long so that detection time can be less than the time required to adjust the frequency offset of the PLL to an accuracy required by a matched filter. The first and second pulses can comprise a known bit pattern or a pseudo-random bit pattern. It is also advantageous if the first and second pulses are DC-balanced so that an unbalanced charge does not accumulate on the link 16. Some examples of DC-balanced signaling are Manchester pulses and differential Manchester pulses. Accordingly, the first and second pulses can comprise symbols (bits 0 and 1) encoded using Manchester encoding or differential Manchester encoding (DME).

An example of a short pulse could be a DME 1, DME 0, DME 0, DME 1. Each rectangle shown in FIGS. 5, 6, 8, 9, 10, 11,12, 13, and 16 comprises the short pulse described above. The rectangles shown in FIG. 4 represent long sequences described above in the description of FIG. 4.

FIG. 7 shows a method 200 to synchronize the startup between two devices (the master and slave devices 12, 14) prior to training. At 202, the master device 12 (e.g., the first pulse generator 102) periodically (in intervals with spacing/duration set as described below) sends short pulses (first pulses) that are few symbols long over the link 16. At 204, the slave device 14 (e.g., the second pulse detector 154) detects the first pulses by detecting energy of the first pulses on the link 16 instead of using a matched filter to detect the first pulses.

At 206, the slave device 14 (e.g., the second control circuit 150, based on the output of the second pulse detector 154) determines if a sufficient number (e.g., a first predetermined number) of the first pulses are received from the master device 12. If not (i.e., if sufficient number of the first pulses are not received), the method 200 returns to 204. Otherwise (i.e., if sufficient number of the first pulses are received), at 208, the slave device 14 (e.g., the second pulse generator 152) sends offset pulses (second pulses) to the master device 12 over the link 16. That is, at 208, the slave device 14 sends offset pulses to the master device 12. The offset pulses are described below in detail.

At 210, the master device 12 (e.g., the first control circuit 100, based on the output of the first pulse detector 104, which in turn is based on detecting energy of the second pulses on the link 16) determines if a sufficient number (e.g., a second predetermined number) of the second pulses are received from the slave device 14. If not (i.e., if sufficient number of the second pulses are not received), at 212, the master device 12 continues to send the first pulses on the link 16, and the method 200 returns to 210. Otherwise (i.e., if sufficient number of the second pulses are received), at 214, the master device 12 stops sending the first pulses to the slave device 14 over the link 16. The sufficient pulses are those in the expected windows as shown in FIGS. 9-13, which are described below. While some noise may be encountered outside these windows, the noise outside these windows is not counted.

At 216, the slave device 14 (e.g., the second control circuit 150, based on the output of the second pulse detector 154) determines if enough of the first pulses from the master device 12 are missed (not received, e.g., over a predetermined time period). If not (i.e., if enough of the first pulses are not missed), at 218, the slave device 14 continues to send the offset pulses (second pulses) to the master device 12 over the link 16, and the method 200 returns to 216. Otherwise (i.e., if enough of the first pulses are missed), at 220, the slave device 14 stops sending the offset pulses (second pulses) to the master device 12 over the link 16. At this point, the startup between the master and slave devices 12, 14 is synchronized, and the slave device 14 is ready for further operations.

### Randomizing Pulses to Account for Noise and Reflection

A noise source that is periodic can be mistaken for a periodic signal sent by the devices 12, 14. To make the above pulse exchange more reliable in the presence of noise, the pulse output can be randomized. One method to randomize the pulse output can be to use a pseudo-random sequence to determine whether to send 1 vs 2 pulses per interval. An interval is a recurring (repeating) period of a fixed duration (set as described below) in which pulse or pulses representing a 0 or a 1 of the pseudo-random sequence are transmitted as described below. Alternatively or additionally, the pulse or pulses can be placed at different positions in time within the interval as described below in detail.

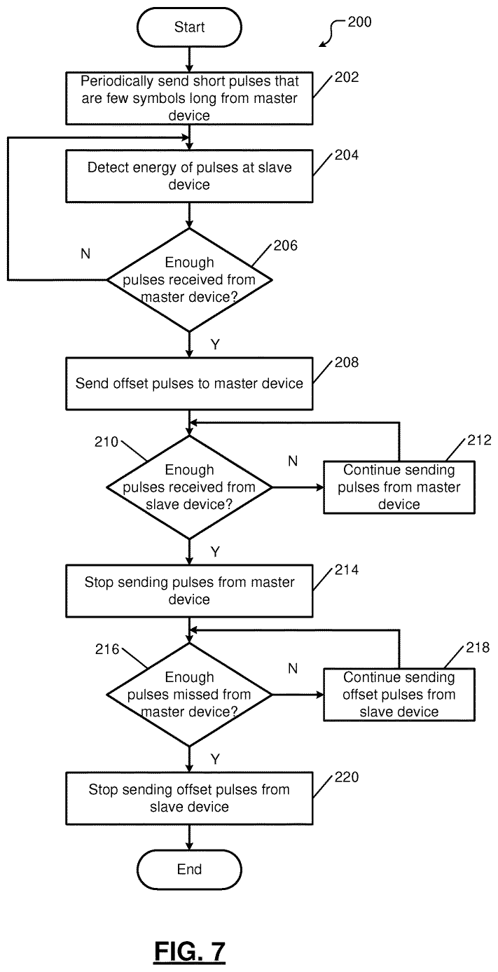

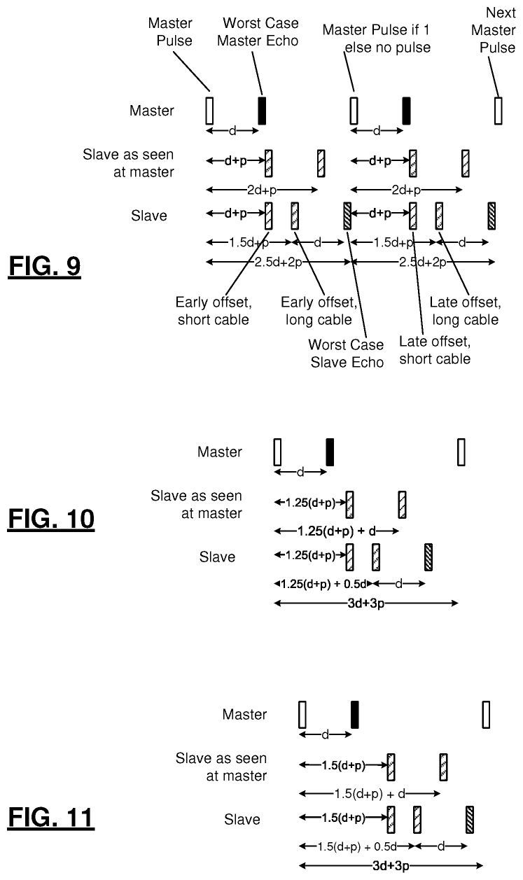

FIG. 8 shows an example of both methods of randomizing pulse output operating concurrently. For example, in an interval, the master device 12 outputs one pulse for a pseudo-random bit 0 (e.g., at the start of the interval) and outputs two pulses for a pseudo-random bit 1 (e.g., one pulse at the start of the interval and another pulse between the start and the end of the interval, e.g., approximately in the middle of the interval). The slave device 14 outputs an early offset pulse (closer to but delayed from the start of the interval) for a pseudo-random bit 0 and a late offset pulse (closer to but before the end of the interval) for a pseudo-random bit 1.

The two devices (master and slave devices 12, 14) can lock on to pseudo-random sequences of each other and can additionally detect whether the sequence is followed (continued) after the lock. The reliability of the detection increases as more intervals are checked after the lock and as the sequence is detected in these additionally checked intervals after the lock. Occasional mismatches can be allowed to account for noise.

The interval spacing (length or duration of the intervals set by the master device 12) and offset spacing (from start and end of the intervals set by the slave device 14) account for pulse duration and propagation delay of the signal between shortest and longest cables linking the two devices 12, 14. Let p denote pulse width of the pulse, and let d denote round trip propagation delay of a signal over the link 16. To prevent a device from seeing its own signal due to reflection, a minimum spacing between the pulse of the master device 12 and the offset pulse of the slave device 14 and vice versa should be no less than d+p.

In FIGS. 9-11 show examples of the interval spacing and offset spacing. In FIG. 9, to achieve the proper spacing so that a device will not see its own reflected signal, the early offset for pulses transmitted from the slave device 14 can be set to d+p from the start of the interval, and the late offset for pulses transmitted from the slave device 14 can be set to d+p from the middle of the interval. The first pulse from the master device 12 (e.g., the pulse for a pseudo-random bit 0 or a first pulse for a pseudo-random bit 1) can be placed at the start of the interval. The second pulse from the master device 12 (a second pulse for a pseudo-random bit 1) can be placed in the middle of the interval at 2.5d+p from the start of the interval.

For the shortest cable, assuming no propagation delay, the pulse placement described above at d+p and 3.5d+2p satisfies the spacing. For the longest cable, the slave device 14 does not see the pulse from the master device 12 until d/2. The offset pulse is output from the slave device 14 at d/2+(d+p) or at d/2+(3.5d+2p). The offset pulse is seen at the master device 12 at d/2+d/2+(d+p) or at d/2+d/2+(3.5d+2p). Hence the total period (duration) of the interval to maintain no overlap is 5d+4p.

FIGS. 10 and 11 show additional examples of the interval spacing and offset spacing. While shifting the slave pulse by an offset of d+p is sufficient, the receiver of the master device 12 has to set a window where to accept and reject the pulse from the slave device 14. A more practical implementation can allow the interval to be larger. For example, an interval of 6(d+p) permits more spacing between pulses by allowing the offset to be larger. Examples of spacing of 1.25(d+p) and 1.5(d+p) are shown in FIGS. 10 and 11, respectively, where only a first half (3d+3p) of the interval 6(d+p) is shown since second half (3d+3p) of the interval is identical to the first half (3d+3p) of the interval 6(d+p).

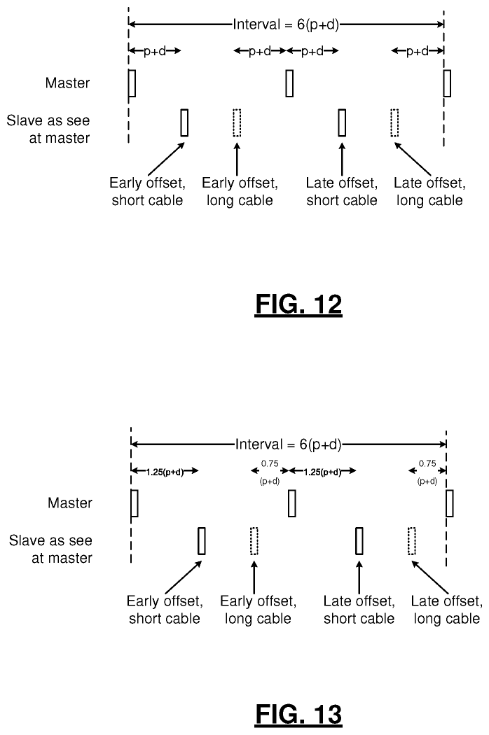

FIGS. 12 and 13 show other examples of the interval spacing and offset spacing. In FIG. 12, to achieve the proper spacing so that a device will not see its own reflected signal, the early offset for pulses transmitted from the slave device 14 can be set to d+p from the start of the interval, and the late offset for pulses transmitted from the slave device 14 can be set to 4(d+p) from the start of the interval. The first pulse from the master device 12 (e.g., the pulse for a pseudo-random bit 0 or a first pulse for a pseudo-random bit 1) can be placed at the start of the interval. The second pulse from the master device 12 (a second pulse for a pseudo-random bit 1) can be placed in the middle of the interval at 3(d+p) from the start of the interval.

For the shortest cable, assuming no propagation delay, the pulse placement described above at d+p and 4(d+p) satisfies the spacing. For the longest cable, the slave device 14 does not see the pulse from the master device until d/2. The offset pulse is output from the slave device 14 at d/2+(d+p) or at d/2+4(d+p). The offset pulse is seen at the master device 12 at d/2+d/2+(d+p) or at d/2+d/2+4(d+p). Hence the total period of the interval to maintain a spacing of p+d for all pulses as seen at the master device 12 is 4p+6d. To simplify the implementation, the interval can be assumed to be 6(p+d). FIG. 13 shows another example of the interval spacing and offset spacing.

### Handling Higher Frequency Offsets Between Clocks

The above methods assume that the offset between the local clocks of the master and slave devices 12, 14 is minimal. However, in crystal-less systems (i.e., with slave devices not using a fixed clock reference such as a crystal oscillator), the clock frequencies of the two local clocks of the master and slave devices 12, 14 can be off by more than +/−15% before locking. The following mechanism works well even when the frequency offset between the local clocks of the master and slave devices 12, 14 is much greater than +/−15%.

For example, one method is to allow the local clock of the slave device 14 (the second clock, also called the slave clock for convenience) to be a free-running clock generated without using a fixed clock reference such as a crystal oscillator. The number of clock cycles of the slave clock between the intervals can be estimated by counting (e.g., using the timer) the number of clock cycles of the slave clock between the pulses (the first pulses received from the master device 12). After counting for several intervals, an average number of clock cycles between the pulses will center around N/2 and N. The slave device 14 can then output the early offset pulse at approximately N/6 clock cycles and the late offset pulse at 4N/6 clock cycles.

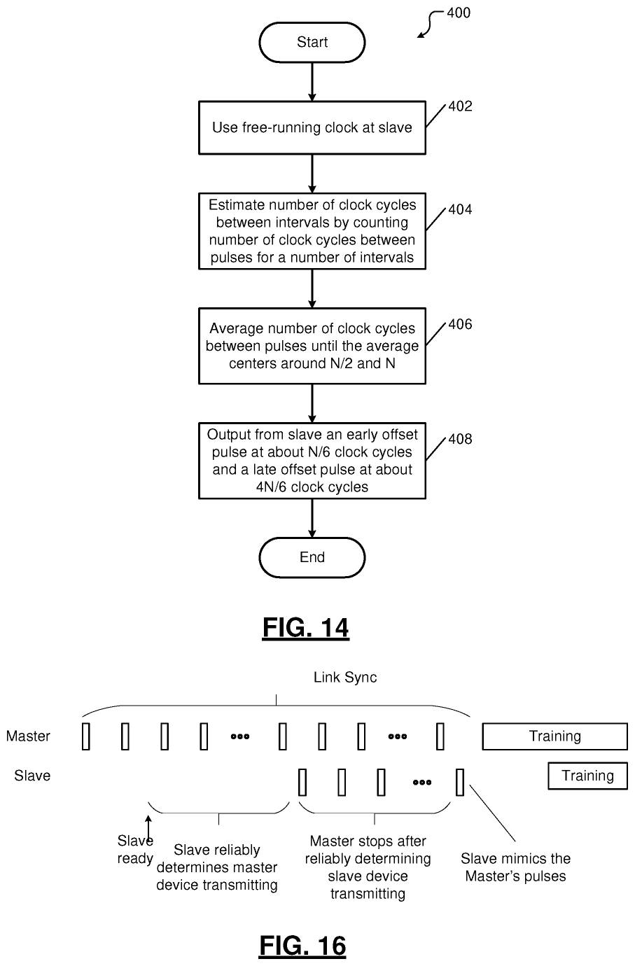

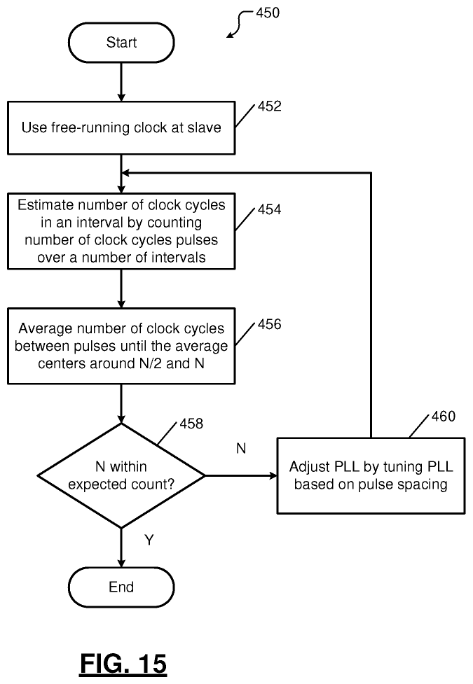

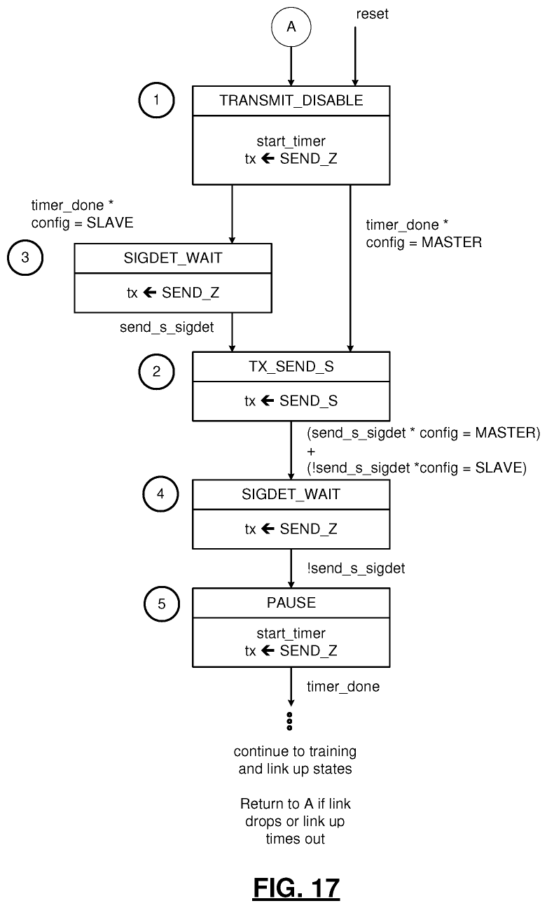

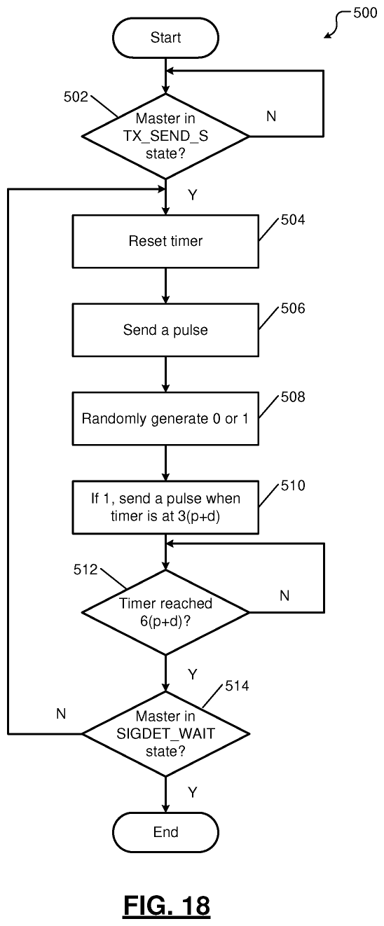

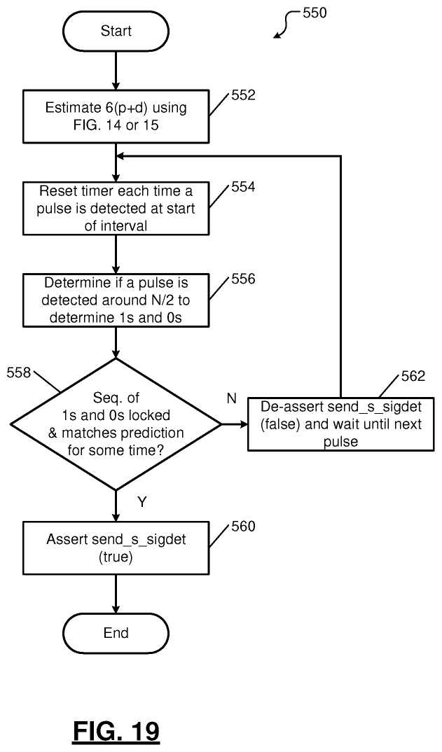

FIG. 14 shows a method 400 of sending the offset pulses from the slave device 14 when the local clock of the slave device 14 is allowed to be a free-running clock. At 402, the second clock generated by the second clock generator 158 of the slave device 14 is allowed to be a free-running clock generated without using a fixed clock reference such as a crystal oscillator. At 404, the second control circuit 150 estimates the number of clock cycles of the second clock between intervals by counting the number of clock cycles (e.g., using the timer) between pulses (the first pulses of the master device 12 in the intervals) over a number of intervals. At 406, the second control circuit 150 calculates an average number of clock cycles between pulses until the average number of clock cycles centers around N/2 and N. Thus, the method 400 estimates a period of 6(p+d) that is equivalent to the count N of the timer clocked by the free-running clock. At 408, the slave device 14 outputs an early offset pulse at about N/6 clock cycles and a late offset pulse at about 4N/6 clock cycles in each interval to maintain no overlap with the first pulses of the master device 12 in each interval.

Another method is to adjust the PLL of the second clock generator 158 of the slave device 14 until N is within an expected count with no frequency offset. Using this method, while it may not be possible to get the frequency offset within the +/−2% requirement needed for a matched filter to work, this method provides the PLL a good starting point when entering the training phase.

For example, the following procedure can be used to tune the PLL: Speed up (increase the frequency of) the PLL if the pulse spacing is less than the optimal N/2, slow down (decrease the frequency of) the PLL if the pulse spacing is greater than N, and do nothing (keep the frequency of the PLL unchanged) if the pulse spacing is between the optimal N/2 and N. In practice, the interval period should be longer than 6(p+d) to account for the frequency offset between the local clocks of the two devices (the master and slave devices 12, 14).

FIG. 15 shows a method 450 of adjusting the slave clock. Steps 452, 454, and 456 of the method 450 are same as steps 402, 404, and 406 of the method 400 and are therefore not described again for brevity. At 458, the second control circuit 150 determines whether N is within an expected count. The method 450 ends if N is within an expected count. If N is not within an expected count, at 460, the second control circuit 150 adjusts the PLL of the second clock generator 158 of the slave device 14, and the method 450 returns to 454 so that N can be computed again. This loop is repeated until N is within an expected count with no frequency offset between the first and second clocks of the master and slave devices 12, 14. The second control circuit 150 adjusts the PLL by tuning the PLL based on the pulse spacing (spacing between the first pulses of the master device 12) in ways described above. Thus, the method 450 estimates a period of 6(p+d) using a target number N that is equivalent to the period of 6(p+d) and by tuning the PLL of the free-running clock generator.

### Example Implementation

An example of an implementation of the above systems and methods is described below. The pseudo-ransom sequence is a 255-length sequence with the sequence of each device uncorrelated. For example, the polynomials of the pseudo-random sequence are:
master(x)=x⁸+x⁴+x³+x²+1
slave(x)=x⁸+x⁶+x⁵+x⁴+1

In an asymmetrical system, where communication in one direction is faster than another (speeds of the master and slave devices 12, 14 are different), the polynomials can be associated with fast and slow directions instead of the master and slave assignments. The pseudo-random outputs are converted to DME pulses, where a logic 0 has no center transition in a DME bit cell and a logic 1 has a center transition in a DME bit cell.

Pulse width=4 DME symbol periods. Round trip propagation delay=20 DME symbol periods. To be conservative, an interval of 6×32 DME symbol periods=192 DME symbol periods is selected. The slave device 14 can adjust the PLL frequency at the same time the slave device 14 is searching for pulse boundaries and locking to the pseudo-random sequence of the first pulses from the master device 12. The master device 12 can look for (detect) the slave pulses anytime between the 24^{th} to 72^{nd} and 120^{th} to 168^{th} DME symbol periods from the start of the interval.

### Simplification

In FIG. 16, in some examples, to simplify design, the pulse randomization (offsetting of pulses) described above can be omitted if a periodic noise source is not a concern. The interval can be shortened by 50% (to 3(d+p)) since there is only one pulse per interval instead of possibly two pulses per interval. The slave device 14 can also mimic the pulses of the master device 12 for simplification instead of independently timing the spacing (e.g., by using offsets described above). This can be useful when the slave device 14 is crystal-less and does not have a stable clock reference such as a crystal oscillator.

### State Diagram

FIG. 17 shows a state diagram (state machine) of how the master and slave devices 12, 14 interact to synchronize link between them. SIGDET and sigdet are abbreviations of signal detect. Starting at the TRANSMIT_DISABLE state upon power-on reset, a delay is introduced to make the link 16 quiet prior to starting link synchronization (as shown at 1). The master device 12 starts by sending SEND_S pulses in the TX_SEND_S state (as shown at 2). The slave device 14 waits quietly in the SIGDET_WAIT state (as shown at 3). Once the slave device 14 detects reliable SEND_S signal from the master device 12 (send_s_sigdet), the slave device 14 moves into the TX_SEND_S state (as shown at 3). When the master device 12 sees a reliable SEND_S signal from the slave device 14, the master device 12 moves to the SIGDET_WAIT state (as shown at 4). When the slave device 14 sees the SEND_S signal from the master device 12 disappear, the slave device 14 also moves into the SIGDET_WAIT state (as shown at 4) and then into the PAUSE state (as shown at 5). When the master device 12 sees the SEND_S signal from the slave device 14 disappear, the master device 12 also moves into the PAUSE state (as shown at 5). Once in the PAUSE state, the link synchronization phase is complete, and the state machine continues onto training and normal operation at both the master and slave devices 12, 14. If the training fails or if the link drops after linking up, the process is restarted by entering into the TRNSMIT_DISABLE state.

In FIG. 17, a SEND_S pulse is a short pulse of energy. For example, the SEND_S pulse can be a 4-bit pulse of 1001 mapped to DME symbols. At the master device 12, each DME symbol-time is nominally within a tight tolerance (e.g., +/−50 ppm) since the master device 12 uses a fixed clock reference such as the crystal oscillator 112 as a clock reference. At the slave device 14, each DME symbol-time can vary by a large percentage (e.g., +/−10%) since there is no reliable (stable or fixed) clock reference such as a crystal oscillator at the slave device 14 and the slave device 14 has to rely on the SEND_S pulses from the master device 12 to get a rough indication of time.

At the master device 12, the SEND_S signal can be a periodic signal with a SEND_S pulse sent every 3(d+p) period, with the signal being quiet (no pulse sent) most of the time. When the slave device 14 detects sufficient number of SEND_S pulses from the master device 12 to determine that the master device 12 is active, the slave device 14 can output a SEND_S signal defined as follows. The SEND_S signal is normally quiet, with the SEND_S pulse being output at least at d+p after the detection of the start of the SEND_S pulse received from the master device 12 at the receiver of the slave device 14. Since the clock reference of the slave device 14 is unreliable, the interval can be set to something larger than 2.5d+2p so that the slave device 14 does not have to send out a pulse exactly at d+p after detecting the SEND_S pulse from the master device 12.

For example, assume that one DME symbol-time is 8.533 ns, the worst-case round trip delay is 36 symbol-times, and the SEND_S pulse has 4 DME symbols. So, 3(d+p)×8.5333=1024 ns. The delay in sending SEND_S can be set to a value varying between 384 ns to 486 ns, for example. Relaxing the delay requirement is useful when the slave device 14 does not have an accurate clock reference.

In FIG. 17, send_s_sigdet indicates whether sufficient SEND_S pulses of the SEND_S signal were detected. The value of the send_s_sigdet is TRUE when the SEND_S signal is detected and FALSE when the SEND_S signal is not detected. At least N (e.g., 3) consecutive valid SEND_S pulses should be detected before setting send_s_sigdet from FALSE to TRUE. A period of at least M clock cycles with no SEND_S pulses detected should elapse before setting send_s_sigdet from TRUE to FALSE.

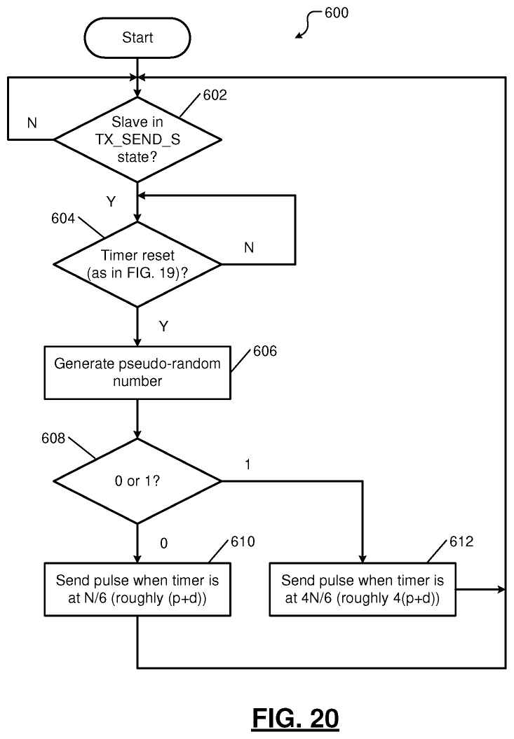

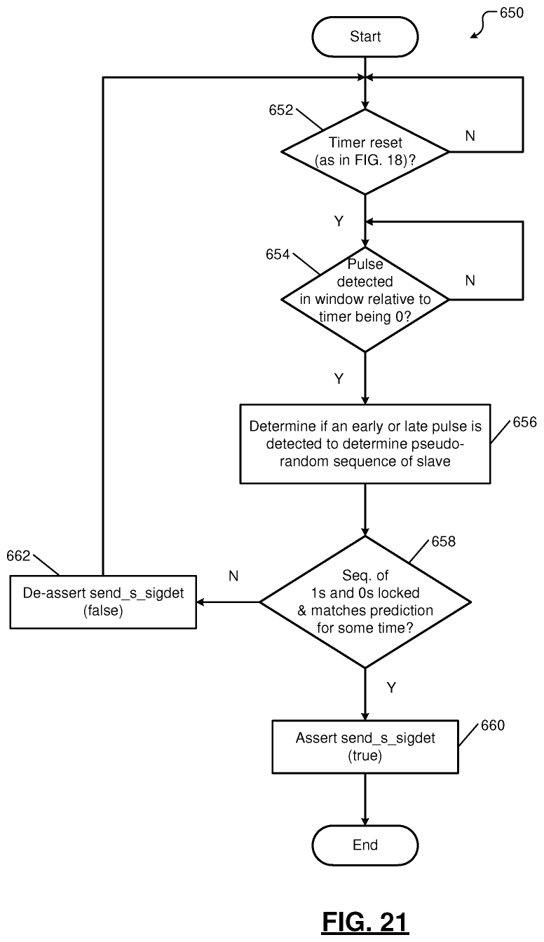

FIGS. 18 and 19 respectively show flowcharts of methods of the master device 12 transmitting SEND_S pulses and the slave device 14 detecting the SEND_S pulses with references made to the state diagram shown in FIG. 17. FIGS. 20 and 21 respectively show flowcharts of methods of the slave device 14 transmitting SEND_S pulses and the master device 12 detecting the SEND_S pulses with references made to the state diagram shown in FIG. 17. The methods shown in FIGS. 18 and 21 are performed by the control circuit 100 of the master device 12, and the methods shown in FIGS. 19 and 20 are performed by the control circuit 150 of the slave device 14.

FIG. 18 shows a method 500 performed by the master device 12 for transmitting SEND_S pulses (also called the first pulses in the description above). The master device 12 transmits when in the TX_SEND_S state shown at 2 in FIG. 17. At 502, the method 500 determines if the master device 12 is in the TX_SEND_S state. If the master device 12 is not in the TX_SEND_S state, the method 500 waits until the master device 12 is in the TX_SEND_S state. If the master device 12 is in the TX_SEND_S state, at 504, the master device 12 (the control circuit 100) resets the timer 110. At 506, the master device 12 (the pulse generator 102) sends a pulse. At 508, the master device 12 randomly generates 0 or 1. At 510, if the randomly generated number is 1, the master device 12 (the pulse generator 102) sends a pulse when the timer 110 is at 3(p+d). At 512, the method 500 (the control device 100) checks whether the timer 110 has reached 6(p+d). If the timer 110 has not reached 6(p+d), the method 500 waits until the timer 110 has reached 6(p+d). If the timer 110 has reached 6(p+d), at 514, the method 500 checks if the master device 12 has transitioned to the SIGDET_WAIT state shown at 4 in FIG. 17. If the master device 12 has not transitioned to the SIGDET_WAIT state (i.e., if the master device 12 is still in the TX_SEND_S state), the method 500 returns to 504. The method 500 ends when the master device 12 transitions to the SIGDET_WAIT state.

FIG. 19 shows a method 550 performed by the slave device 14 for detecting pulses (also called the first pulses in the description above). The slave device 14 performs the method 550 when in the SIGDET_WAIT state shown at 3 in FIG. 17, in the TX_SEND_S state shown at 2 in FIG. 17, and in the SIGDET_WAIT state shown at 4 in FIG. 17. At 552, the slave device 14 estimates 6(p+d) using the method of FIG. 14 or FIG. 15. As already described above, the method 400 of FIG. 14 determines the count N for the timer 160, which is clocked by the free-running clock generator 158, that is equivalent to the period 6(p+d); and the method 450 of FIG. 15 estimates the period of 6(p+d) using a target number N that is equivalent to the period of 6(pad) and by tuning the PLL of the free-running clock generator 158. After estimating 6(p+d), the pulse detector 154 of the slave device 14 expects to detect a pulse approximately every time the timer 160 reaches the count N. The slave device 14 detects pulses and determines the pulses that are at the start of the interval versus the pulses that are in the center of the interval.

At 554, the slave device 14 (the control circuit 150) resets the timer 160 each time a pulse is detected by the pulse detector 154 at the start of the interval. At 556, the method 550 determines if a pulse is detected by the pulse detector 154 around N/2 (in the center of the interval) to determine 1s and 0s. At 558, the slave device 14 determines if the pseudo-random sequence of 1s and 0s is locked and matches a predicted sequence for a predetermined time period. If the sequence is locked and matches the predicted sequence for the predetermined time period, at 560, the slave device 14 asserts send_s_sigdet (sets send_s_sigdet=true), and the method 550 ends. If the sequence does not match the predicted sequence a predetermined number of times or if the slave device 14 does not detect pulses, at 562, the slave device 14 de-asserts send_s_sigdet (sets send_s_sigdet=false), the slave device 14 waits until a next pulse is detected, and the method 550 returns to 554 to reacquire lock.

FIG. 20 shows a method 600 performed by the slave device 14 for transmitting pulses (also called the second pulses in the description above). The slave device 14 transmits when in the TX_SEND_S state shown at 2 in FIG. 17. At 602, the method 600 determines if the slave device 14 is in the TX_SEND_S state. If the slave device 14 is not in the TX_SEND_S state, the method 600 waits until the slave device 14 is in the TX_SEND_S state. If the slave device 14 is in the TX_SEND_S state, at 604, the slave device 14 resets the timer 160 (note that the timer 160 is periodically reset in FIG. 19). At 606, the slave device 14 randomly generates 0 or 1. At 608, the method 600 determines if the randomly generated number is 0 or 1. If the randomly generated number is 0, at 610, the slave device 14 (the pulse generator 152) sends a pulse when the timer 160 is at N/6 (roughly (p+d)), and the method 600 returns to 602. If the randomly generated number is 1, at 612, the slave device 14 (the pulse generator 152) sends a pulse when the timer 160 is at 4N/6 (roughly 4(p+d)), and the method 600 returns to 602.

FIG. 21 shows a method 650 performed by the master device 12 for detecting pulses (also called the second pulses in the description above). At 652, the method 650 determines if the timer 110 is reset (note that the timer 110 is periodically reset in FIG. 18). The method 650 waits until the timer 110 is reset. If the timer 110 is reset, at 654, the method 650 determines if the pulse detector 104 detected a pulse in the window shown in FIG. 9 relative to the timer 110 being reset to 0 (see the row identified by “Slave as seen at master” in FIG. 9). The method 650 waits until the pulse detector 104 detects a pulse in the window. If a pulse is detected in the window, at 656, the method 650 determines if an early or late pulse is detected to determine a pseudo-random sequence of the slave device 14. At 658, the method 650 determines if the pseudo-random sequence of 1s and 0s is locked and matches a predicted sequence for a predetermined time period. If the sequence is locked and matches the predicted sequence for the predetermined time period, at 660, the master device 12 asserts send_s_sigdet (sets send_s_sigdet=true), and the method 650 ends. If the sequence does not match the predicted sequence a predetermined number of times or if the master device 12 does not detect pulses, at 662, the master device 12 de-asserts send_s_sigdet (sets send_s_sigdet=false), and the method 650 returns to 652 to reacquire lock.

FIGS. 17-21 show five interacting methods. Specifically, the methods of FIGS. 18-21 interact with the state diagram (state machine) shown in FIG. 17. The methods of FIGS. 18-21 can also be implemented as state machines and therefore can also be considered as state diagrams similar to the state diagram shown in FIG. 17. Both master and slave devices 12, 14 comprise and can execute the method (state machine) of FIG. 17. The master device 12 comprises and can execute the methods (state machines) of FIGS. 18 and 21. The slave device 14 comprises and can execute the methods (state machines) of FIGS. 19 and 20.

While not shown, the five methods (state machines) shown in FIGS. 17-21 can be merged into fewer than five methods (state machines). The five methods (state machines) shown in FIGS. 17-21 can also be simplified if the randomization is not performed. For example, the methods of FIGS. 17 and 18 (without randomization) and FIG. 20 (without randomization) can be merged into one state diagram (state machine) that can be executed by both the master and slave devices 12, 14. In executing such as merged method (state machine), the master device 12 can elect one path (flow) of the merged method (state machine) and the slave device 14 can elect another path (flow) of the merged method (state machine).

The above systems and methods provide an alternate link synchronization mechanism that has the desirable properties (one device limits its transmit signal until both devices are present and ready to start, the detection can be completed quickly, the detection can be reliable in the presence of noise) and that avoids the use of an expensive matched filter and the stringent initial frequency offset requirement of the PLL that is required by the matched filter. The alternative mechanism achieves this goal with a detection time that is less than the time required to adjust the frequency offset of the PLL to an accuracy required by the matched filter. The first and second pulses can be relatively short (in duration) and can be only a few symbols long so that detection time can be less than the time required to adjust the frequency offset of the PLL to an accuracy required by the matched filter.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the embodiments described are not mutually exclusive, and permutations of one or more embodiments with one another remain within the scope of this disclosure.

As used herein, the phrase at least one of A, B, and C should be construed to mean a logical (A OR B OR C), using a non-exclusive logical OR, and should not be construed to mean “at least one of A, at least one of B, and at least one of C.” In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “control circuit” and other elements (components) shown in FIGS. 3 and 4 (generally called circuits) may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The term code, as used above, may include software, firmware, and/or microcode, and may refer to programs, routines, functions, classes, data structures, and/or objects. The term shared processor circuit encompasses a single processor circuit that executes some or all code from multiple circuits. The term group processor circuit encompasses a processor circuit that, in combination with additional processor circuits, executes some or all code from one or more circuits. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple circuits. The term group memory circuit encompasses a memory circuit that, in combination with additional memories, stores some or all code from one or more circuits.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

In this application, apparatus elements described as having particular attributes or performing particular operations are specifically configured to have those particular attributes and perform those particular operations. Specifically, a description of an element to perform an action means that the element is configured to perform the action. The configuration of an element may include programming of the element, such as by encoding instructions on a non-transitory, tangible computer-readable medium associated with the element.

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

1. A method comprising:
periodically sending first pulses from a master device to a slave device;
detecting energy of the first pulses at the slave device;
sending second pulses from the slave device to the master device upon detecting energy of a first predetermined number of the first pulses at the slave device, the second pulses being offset relative to the first pulses;
ceasing sending the first pulses from the master device to the slave device after receiving a second predetermined number of the second pulses from the slave device at the master device; and
ceasing sending the second pulses from the slave device to the master device after not receiving any pulse from the master device at the slave device for a predetermined time period.

2. The method of claim 1 wherein the first and second pulses comprise a pseudo-random pattern.

3. The method of claim 1 wherein the first and second pulses comprise data encoded by Manchester encoding or differential Manchester encoding.

4. The method of claim 1 further comprising sending the first and second pulses spaced within intervals, wherein the first and second pulses have a first duration, and wherein the intervals have a second duration that is based on the first duration and a round-trip propagation delay on a cable connecting the master and slave devices.

5. The method of claim 4 further comprising sending the first and second pulses such that, in each interval, a spacing between one of the first pulses and one of the second pulses is at least a sum of the first duration and the round-trip propagation delay.

6. The method of claim 4 further comprising setting the second duration of the intervals based on a length of the cable.

7. The method of claim 4 further comprising setting the second duration of the intervals to a multiple of a sum of the first duration and the round-trip propagation delay.

8. The method of claim 4 further comprising:
sending the first and second pulses to represent one bit in each interval;
sending the first pulses comprising sending, in each interval, one pulse for a bit 0 or two pulses for a bit 1; and
sending the second pulses comprising sending, in each interval, one pulse for a bit 0 or one pulse for a bit 1.

9. The method of claim 8 further comprising:
positioning, in sending the first pulses in each interval, the one pulse for a bit 0 or a first one of the two pulses for a bit 1 at a start of the interval, and a second one of the two pulses for a bit 1 in middle of the interval; and
positioning, in sending the second pulses in each interval, the one pulse for a bit 0 at a first offset relative to the start of the interval, and the one pulse for a bit 1 at a second offset relative to the start of the interval or relative to middle of the interval.

10. The method of claim 9 further comprising:
setting the first offset equal to a sum of the first duration and the round-trip propagation delay; and
setting the second offset equal to a multiple of the first offset when measured from the start of the interval or equal to the sum of the first duration and the round-trip propagation delay when measured from the middle of the interval.

11. The method of claim 10 further comprising, at the slave device:
generating a clock without using a crystal oscillator;
counting number of cycles of the clock between the first pulses for a plurality of the intervals;
determining an average count of the cycles of the clock per interval; and
setting the first and second offsets based on the average count.

12. The method of claim 4 further comprising, at the slave device:
generating a clock without using a crystal oscillator;
counting number of cycles of the clock between the first pulses for a plurality of the intervals; and
determining an average count of the cycles of the clock per interval.

13. The method of claim 10 further comprising, at the slave device:
generating a clock without using a crystal oscillator;
counting number of cycles of the clock between the first pulses for a plurality of the intervals;
determining an average count of the cycles of the clock per interval; and
adjusting the clock until the average count is within a predetermined range of an expected count without a frequency offset between the clock at the slave device and a clock at the master device.

14. The method of claim 4 further comprising, at the slave device:
generating a clock without using a crystal oscillator;
counting number of cycles of the clock between the first pulses for a plurality of the intervals;
determining an average count of the cycles of the clock per interval; and
adjusting the clock until the average count is within a predetermined range of an expected count without a frequency offset between the clock at the slave device and a clock at the master device.

15. The method of claim 4 further comprising:
sending the first and second pulses to represent one bit in each interval;
sending, in each interval, the first pulses comprising one pulse for a bit 0 and one pulse for a bit 1, each having the first duration and a spacing within the interval; and
sending, in each interval, the second pulses comprising one pulse for a bit 0 and one pulse for a bit 1, each having the first duration and the spacing within the interval.

16. The method of claim 4 further comprising, when noise is to be disregarded, halving the second duration by including a single pulse in each of the first and second pulses.

17. A system comprising:
a master device comprising:
a first pulse generator configured to generate and periodically send first pulses over a cable; and
a first pulse detector configured to detect incoming pulses on the cable; and
a slave device coupled to the master device by the cable, the slave device comprising:
a second pulse detector configured to detect the first pulses on the cable; and
a second pulse generator configured to generate and send second pulses over the cable in response to the second pulse detector detecting a first predetermined number of the first pulses on the cable, the second pulses being offset relative to the first pulses;
wherein the first pulse generator is configured to stop sending the first pulses in response to the first pulse detector detecting a second predetermined number of the second pulses on the cable; and
wherein the second pulse generator is configured to stop sending the second pulses after the second pulse detector not detecting any pulse from the master device for a predetermined time period.

18. The system of claim 17 wherein the first and second pulses comprise a pseudo-random pattern.

19. The system of claim 17 wherein the first and second pulses comprise data encoded by Manchester encoding or differential Manchester encoding.

20. The system of claim 17 wherein:
the first and second pulse generators are configured to send the first and second pulses spaced within intervals;
the first and second pulses have a first duration; and
the intervals have a second duration that is based on the first duration and a round-trip propagation delay on the cable.

21. The system of claim 20 wherein the first and second pulse generators are configured to send the first and second pulses such that, in each interval, a spacing between one of the first pulses and one of the second pulses is at least a sum of the first duration and the round-trip propagation delay.

22. The system of claim 20 wherein the second duration of the intervals based on a length of the cable.

23. The system of claim 20 wherein the second duration of the intervals is a multiple of a sum of the first duration and the round-trip propagation delay.

24. The system of claim 20 wherein:
the first and second pulse generators are configured to send the first and second pulses to represent one bit in each interval;
the first pulse generator is configured to send the first pulses comprising, in each interval, one pulse for a bit 0 or two pulses for a bit 1; and
the second pulse generator is configured to send the second pulses comprising, in each interval, one pulse for a bit 0 or one pulse for a bit 1.

25. The system of claim 24 wherein:
the first pulse generator is configured to position, in sending the first pulses in each interval, the one pulse for a bit 0 or a first one of the two pulses for a bit 1 at a start of the interval, and a second one of the two pulses for a bit 1 in middle of the interval; and
the second pulse generator is configured to position, in sending the second pulses in each interval, the one pulse for a bit 0 at a first offset relative to the start of the interval, and the one pulse for a bit 1 at a second offset relative to the start of the interval or relative to middle of the interval.

26. The system of claim 25 wherein the second pulse generator is configured to set:
the first offset equal to a sum of the first duration and the round-trip propagation delay; and
the second offset equal to a multiple of the first offset when measured from the start of the interval or equal to the sum of the first duration and the round-trip propagation delay when measured from the middle of the interval.

27. The system of claim 26 wherein the slave device further comprises:
a clock generator configured to generate a clock without using a crystal oscillator; and
a control circuit configured to:
count number of cycles of the clock between the first pulses for a plurality of the intervals;
determine an average count of the cycles of the clock per interval; and
set the first and second offsets based on the average count.

28. The system of claim 20 wherein the slave device further comprises:
a clock generator configured to generate a clock without using a crystal oscillator; and
a control circuit configured to:
count number of cycles of the clock between the first pulses for a plurality of the intervals; and
determine an average count of the cycles of the clock per interval.

29. The system of claim 26 wherein the slave device further comprises:
a clock generator configured to generate a clock without using a crystal oscillator; and
a control circuit configured to:
count number of cycles of the clock between the first pulses for a plurality of the intervals;
determine an average count of the cycles of the clock per interval; and
adjust the clock until the average count within a predetermined range of an expected count without a frequency offset between the clock and a clock at the master device.

30. The system of claim 20 wherein the slave device further comprises:
a clock generator configured to generate a clock without using a crystal oscillator; and
a control circuit configured to:
count number of cycles of the clock between the first pulses for a plurality of the intervals;
determine an average count of the cycles of the clock per interval; and
adjust the clock until the average count within a predetermined range of an expected count without a frequency offset between the clock and a clock at the master device.

31. The system of claim 20 wherein:
the first and second pulse generators are configured to send the first and second pulses to represent one bit in each interval;
the first pulse generator is configured to send, in each interval, the first pulses comprising one pulse for a bit 0 and one pulse for a bit 1, each having the first duration and a spacing within the interval; and
the second pulse generator is configured to send, in each interval, the second pulses comprising one pulse for a bit 0 and one pulse for a bit 1, each having the first duration and the spacing within the interval.

32. The system of claim 20 wherein the second duration is halved by including a single pulse in each of the first and second pulses when noise is to be disregarded.

33-88. (canceled)
